(19) United States
(12) Patent Application Publication
(10) Pub. No.: US 2008/0119008 A1
(43) Pub. Date: May 22, 2008

(54) Molecular Device and Manufacturing Method for the Same

(76) Inventors: Yuji Miyato, Kyoto (JP); Kei Kobayashi, Kyoto (JP); Hirofumi Yamada, Kyoto (JP); Kazumi Matsushige, Kyoto (JP)

Correspondence Address: HARNESS, DICKEY & PIERCE, P.L.C., P.O. BOX 8910, RESTON, VA, 20195, US

(21) Appl. No.: 11/661,316

(22) PCT Filed: Aug. 30, 2005
(86) PCT No.: PCT/JP05/15773

§ 371 Date: Sep. 25, 2007

(30) Foreign Application Priority Data
Aug. 31, 2004 (JP) 2004-253280

(51) Int. Cl. H01L 51/40

(52) U.S. Cl. 438/99; 438/761; 438/762; 977/880

(57) ABSTRACT

A molecular device of the present invention is arranged so that a self-organizing monomolecular layer is formed on an oxide layer made of an oxide of a substrate by being chemically bonded with the surface of the oxide layer, and nano structures are formed on the monomolecular film. With this arrangement, the present invention provides a molecular device which causes less interaction between the substrate and nanostructures arranged on the substrate, thereby realizing easier control of orientation of nano structures on the substrate. The present invention also provides a manufacturing method of the molecular device.

### TECHNICAL FIELD

The present invention relates to a molecular device using a nano structure and a manufacturing method thereof.

### BACKGROUND ART

These days, the semiconductor industry is often called a billion dollar scale market. In such a semiconductor industry, silicon (Si) is used as a major material. The semiconductor device using silicon is developing to be a micro device which is capable of many operations at high speeds, and has a large capacity. The semiconductor device as a micro device is assumed to be further reduced in size in next several tens of years to the integration limitation, wiring limitation and high-frequency limitation, and will eventually face the limitation of the function realized by a silicon micro device. With such a concern of the limitation of micro device, a nanotube, such as a carbon nanotube is attracting increasing attention, as a next-generation device material which can be replacement of a silicon semiconductor device. The various devices using carbon nanotubes are therefore being developed.

Since the nanotube has a micro structure of several nano meters, it is capable of high-integration and exhibits various electrical conduction properties depending on the type of structure. Therefore, in the field of electronics, the nanotube is expected to be used as a micro electronic element such as a capacitor or a transistor, or as a micro wire material. When used in the field of electronics, the nanotube is generally disposed on an insulative substrate of SiO₂ or the like. Therefore, conventionally, various techniques for disposing a nanotube on a predetermined position of a substrate were developed in forming an integrated circuit.

For example, in the case of using a nanotube as a wire for connecting electrodes, the nanotubes are arranged on a substrate by one of the following methods. (a) nanotubes are deposited directly on a predetermined portions of a substrate by a CVD (chemical vapor deposition) method; (b) nanotubes are first dispersed on a substrate, and then are connected to the electrodes by vapor deposition using lithography; (c) each of nanotubes are moved with a scanning probe microscope to form a circuit; or (d) a solvent in which nanotubes are dispersed is dropped between electrodes formed on a substrate, and then each nanotube is disposed between the electrodes by a dielectrophoresis method which applies an alternating voltage between the electrodes (Patent Document 1: Japanese Unexamined Patent Publication Tokukai (Laid-Open) 2003-332266 (published on Nov. 21, 2003).

In disposing a nanotube on a substrate, the nanotube, which has a micro structure, and the surface of the substrate interact with each other with a relatively intensive force. Due to the interaction the nanotubes are not easily released from the substrate, making manipulation of nanotubes difficult. Moreover, the interaction may cause dynamical force or chemical influence to the nanotubes, and therefore the nanotubes are easily changed in property.

Therefore, in disposing the nanotubes on a substrate by one of the foregoing methods (a) to (d), there is a problem of difficulty in positioning nanotubes on the substrate. More specifically, the interaction causes some difficulty in removing a nanotube deposited on a wrong portion of the substrate, that is, the nanotube cannot be easily moved to the right position. Moreover, the interaction also blocks the nanotube from exhibiting the original property.

Note that, a technique related to organic thin film transistor using organic thin film such as pentacene or naphthacene is disclosed in non-patent document 1: S. Kobayashi et al., “Control of carrier density by self-assembled monolayers in organic field-effect transistors”, Nature Mater., Volume 3, p.317, 2004, and non-patent document 2: D. J. Gundlach et al., “Thin-film transistors based on well-ordered thermally evaporated naphthacene films”, Appl. Phys. Lett., Volume 80, p.2925, 2002. The non-patent documents 1 and 2 disclose techniques of improving the carrier mobility by a method of first forming a self-organizing monomolecular layer on an insulative substrate such as SiO₂ using octadecyl trichlorosilane and then forming an organic thin film on the self-organizing monomolecular layer. However, the non-patent documents 1 and 2 do not teach a molecular device using nanotubes.

### DISCLOSURE OF INVENTION

The present invention is made in view of the foregoing conventional problems and an object is to provide a molecular device which causes less interaction between the substrate and nanostructures arranged on the substrate, thereby realizing easier control of orientation of nano structures on the substrate. The present invention also provides a manufacturing method of the molecular device.

In order to solve the foregoing object, a molecular device according to the present invention in which nano structures are arranged on a substrate is arranged so that said substrate includes an oxide layer made of an oxide, the oxide layer including on its surface a hydrophobic membrane which is chemically bonded with the surface, said hydrophobic membrane being a self-organizing monomolecular layer, the nanostructures is arranged on said hydrophobic membrane, said hydrophobic membrane is a self-organizing monomolecular layer, and the nanostructures are arranged on said hydrophobic membrane.

Further, in order to solve the foregoing object, a manufacturing method of a molecular device according to the present invention is a manufacturing method of a molecular device in which nano structures are arranged on a substrate including on its surface an oxide layer made of an oxide, the method comprising the steps of: (i) forming a hydrophobic membrane, which is a self-organizing monomolecular layer, on the oxide on a surface of the oxide layer by chemically bonding the hydrophobic membrane with a surface of the oxide; and (ii) arranging the nano structures on said hydrophobic membrane.

With the foregoing method and device, the substrate includes an oxide layer including on its surface a hydrophobic membrane which is chemically bonded with the surface, and the nano structures are arranged on a substrate via a hydrophobic membrane. Since the hydrophobic membrane hardly interact with nano structures, the provision of the hydrophobic membrane reduces interaction between the substrate and the nano structures. On this account, the nanotubes deposited on a wrong portion of the substrate can be easily removed from the substrate via the hydrophobic membrane, that is, the nanotubes can be easily moved to the right position via the hydrophobic membrane. Further, because the hydrophobic membrane is a self-organizing monomolecular layer, the hydrophobic membrane can be formed with a thickness equal to 1 molecular diameter. Accordingly, the nanostructures can be arranged in desired positions without increasing the size of molecular device. The resulting molecular device is also easily manufactured and superior in reliability.

On this account, the present invention gives an effect of providing a molecular device which causes less interaction between the substrate and nanostructures arranged on the substrate, thereby realizing easier control of orientation of nano structures on the substrate. The present invention also provides a manufacturing method of the molecular device.

With this effect, it becomes possible to dispose a micro electronic element such as a transistor or a capacitor and/or a wire on a desired portion of a substrate. The present invention thus provides a highly-reliable molecular device with a desired circuit layout, and the manufacturing method thereof.

### BRIEF DESCRIPTION OF DRAWINGS

FIG. 1 A cross-sectional view showing a molecular device according to one embodiment of the present invention.

FIG. 2(a) shows a surface picture of silicon substrate on which a monomolecular layer is formed, (b) to (f) are images showing surface potential on application of a predetermined voltage to the Au electrode on the silicon substrate.

FIG. 3(a) shows an AFM image of a silicon substrate on which carbon nanotubes are arranged on a monomolecular layer before ultrasonic cleaning, and (b) shows an AFM image of the silicon substrate after the ultrasonic cleaning.

FIG. 4(a) shows an AFM image of a silicon substrate in which the carbon nanotubes are arranged on a monomolecular layer before the manipulation, and (b) shows an AFM image of the silicon substrate after the manipulation.

FIG. 5(a) to (d) show AFM images of manipulation process of carbon nanotubes arranged on a monomolecular layer formed on a silicon substrate.

FIG. 6(a) shows a surface picture of a silicon substrate not having a monomolecular layer, and (b) to (f) show images of surface potentials on application of predetermined voltages to the Au electrodes of the silicon substrate.

FIG. 7(a) shows an AFM image of a silicon substrate on which carbon nanotubes are arranged without a monomolecular layer before ultrasonic cleaning, and (b) shows an AFM image of the silicon substrate after the ultrasonic cleaning.

FIG. 8(a) shows an AFM image of a silicon substrate in which the carbon nanotubes are arranged without a monomolecular layer before the manipulation, and (b) shows an AFM image of the silicon substrate after the manipulation.

### BEST MODE FOR CARRYING OUT THE INVENTION

First Embodiment

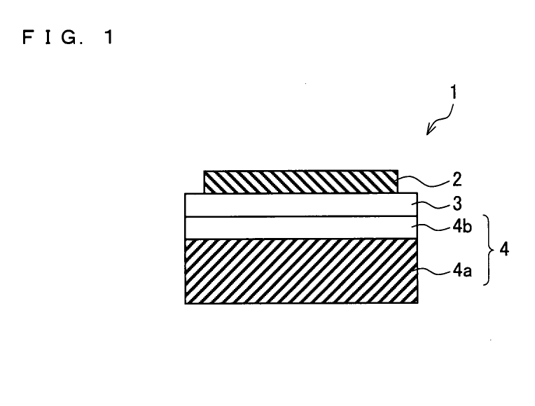

One embodiment of the present invention is described below with reference to FIG. 1. FIG. 1 is a cross-sectional view of a molecular device 1 according to the present invention.

As shown in FIG. 1, the molecular device 1 includes a substrate 4 on which a monomolecular layer (hydrophobic membrane, self-organizing monomolecular layer) 3 and a nanotube (nano structure) 2 are formed in this order.

The substrate 4 includes, for example, a conductive layer 4a and an insulative oxide layer 4b formed of an oxide, and the oxide layer 4b is formed on the surface of the substrate 4. The conductive layer 4a constituting the substrate 4 is not particularly limited, but suitable conductive materials include silicon (Si), titanium (Ti), tantalum (Ta), zirconium (Zr), aluminum (Al).

The oxide layer 4b is formed of an oxide, and its surface is chemically bonded with a molecular layer 3, as described later. The oxide constituting the oxide layer 4b is formed of an oxide of the material of the conductive layer 4a. Suitable examples include SiO₂, TiO₂, ZrO₂, and Al₂O₃. In terms of versatility, silicon and SiO₂ are particularly preferable for the conductive layer 4a and the oxide layer 4b, respectively.

The molecular layer 3 is formed on the oxide layer 4b of the substrate 4. The molecular layer 3 is a self-organizing monomolecular layer whose thickness is equal to 1 molecular diameter. The molecular layer 3 is provided to modify the surface of the substrate 4 to be hydrophobic. Therefore, to realize a micro-sized molecular device 1, it is preferable to use the molecular layer 3. However, the molecular layer 3 may instead be a hydrophobic membrane which exhibits a surface hydrophobic property by chemically coupling with the oxide layer 4b.

As described, the provision of the molecular layer 3 reduces the interaction between the molecular layer 3 and the nanotubes 2. That is, the surface of the oxide layer 4b has a hydroxyl(—OH) group resulted from chemical bond of the 0 atom of the oxide with the H atom. The hydroxyl group existing on the surface of the oxide layer 4b provides hydrophilic property to the oxide layer 4b. When a fine material such as nanotubes 2 is disposed on the oxide layer 4b by using the hydroxyl group, a significant interaction occurs between the oxide layer 4b and the nanotubes 2 via the hydroxyl group. The interaction causes some difficulty in controlling the position of the nanotubes 2 on the substrate 4. This interaction may also give some unwanted influence to the property of the nanotubes 2.

In view of this problem, in the present embodiment, the molecular layer 3 is formed by chemically coupling with the oxide layer 4b due to chemical reaction with the hydroxyl group of the oxide layer 4b. More specifically, the hydroxyl group on the surface of the oxide layer 4b serves as a portion for chemical reaction in forming the molecular layer 3, and the molecular layer 3 is so formed as to cover the surface of the oxide layer 4b. On this account, the substrate 4, which has a hydrophilic surface because of the inclusion of the oxide layer 4b, becomes to have a hydrophobic surface due to the molecular layer 3 makes the surface. Therefore, by providing the nanotubes 2 on the molecular layer 3 formed on the substrate 4, the interaction between the molecular layer 3 and the nanotubes 2 hardly occur. In this manner, the provision of molecular layer 3 greatly reduces the interaction between the substrate 4 and the nanotubes 2, compared with the case where the nanotubes 2 are directly formed on the oxide layer 4b of the substrate 4.

Note that, the molecular layer 3 is any compound which causes chemical bond with a hydroxyl group of the oxide constituting the oxide layer 4b, and forms a hydrophobic surface. Examples of the compound includes an organosilane compound such as
(CH₃)₃Si—NH—Si(CH₃)₃(HMDS:hexamethyldisilazane),
(CH₃)(CH₂)ₗ₇SiCl₃(OTS:octadecyltrichlorosilane),
(CH₃)(CH₂)₇Si(OC₂H₅)₃, (CF₃)(CF₂)(CH₂)₂Si(OC₂H₅)₃,
(CF₃)(CF₂)₇(CH₂)₂Si(OC₂H₅)₃, (NH₂)(CH₂)₃Si(OC₂H₅)₃, or
(CH₃)(CH₂)₇Si(OC₂H₅)₃, and a titanium compound, which is a derivative substitution in which at least one of Cls of TiCl₄ or TiCl₄ is replaced with an organic substituent such as —CH₃ group or —OC₂H₅ group.

Each nanotube 2 is a cylinder-shaped nano structure with a nanometer scale structure used as an electronic element such as a capacitor or a transistor, and/or wires used for a molecular device 1. The nanotube 2 may be a single layer-type, a multilayer-type, a coil-type, or a spiral type. Further, the material of nanotubes 2 is selected from a material ensuring a desired electric a property. Suitable examples include a carbon nanotube, boron carbon nitrogen nanotube (BCN nanotube) and a boron nitrogen nanotube (BN nanotube), in which a part or the whole of the carbons constituting the carbon nanotube is replaced with boron (B) and/or nitrogen (N).

Note that, the nanotubes 2 are used in the present embodiment, but the present invention is not limited to the nanotube but may use a nanowire instead. Suitable examples of nanowire include carbon nanowire; zinc oxide (ZnO) nanowire; covalent bond nanowire such as conductive compound, carbon nanotube, or silicon compound.

As described, the molecular device 1 includes the molecular layer 3 between the surface of the substrate 4 and the nanotubes 2. As described above, the molecular layer 3 is chemically bonded with the oxide layer 4b of the substrate 4 which exhibits a hydrophilic property, thereby showing a hydrophobic property. Therefore, the interaction between the molecular layer 3 and the nanotubes 2 provided thereon is significantly small. Therefore, the molecular device 1 according to the present embodiment greatly reduces the interaction between the oxide layer 4b of the substrate 4 and the nanotubes 2, compared with a conventional molecular device in which a nanotube is directly formed on a substrate.

This allows the nanotubes 2 disposed on the substrate 4 to be moved to an arbitrary position via the molecular layer 3 by manipulation, for example. Further, the nanotubes 2 deposited on an undesired portion of the substrate 4 via the molecular layer 3 may be removed easily from the substrate 4. Further, by reducing the interaction between the molecular layer 3 and the nanotubes 2, the original property of nanotube is ensured. More specifically, provision of the molecular layer 3 easily realizes a molecular device 1 with a desired property.

The following explains a manufacturing method of the molecular device 1 with reference to FIG. 1.

First, as required, an electrode 10 (not shown) is formed on the oxide layer 4b of the substrate 4 (electrode formation process). Next, the surface of the oxide layer 4b of the substrate 4 is washed well, and a molecular layer 3 is formed on the surface of the oxide layer 4b after the surface is processed to be hydrophilic. A preferable method of forming the molecular layer 3 is such that molecular layer 3 is self-organized on the oxide layer 4b. A possible example is heating the substrate 4 and organosilane compound or titanium compound, which is a material of the molecular layer 3 in a hermetic container. Other example may be a CVD method, or solution dipping method. Note that, to ensure good layer quality of the resulting molecular layer 3, the heating is preferably carried out under nitrogen atmosphere, that is, in a state immune to the influence of moisture (humid) in the air. As a result, the molecular layer 3 is formed only on the hydrophilic oxide layer 4b, avoiding the surface of the electrode.

Here, in the case of using HMDS, an organosilane compound is formed to produce the molecular layer 3 by the silane coupling reaction between the M—OH (M indicates an atom other than oxygen constituting the oxide layer). More specifically, the molecular layer 3 is formed by being chemically bonded to the oxide layer 4b, through the chemical reaction expressed by the following formula (1).

2M—OH+(CH₃)₃Si—NH—Si(CH₃)₃ →2M—2M—O—Si(CH₃)₃+NH₃ (1)

Further, in the case of using organosilane compound or titanium compound M′-Cl (M′ denotes a structure other than the Cl terminal portion) with a Cl terminal, the molecular layer 3 is formed by being chemically bonded to the oxide layer 4b, through the chemical reaction expressed by the following formula (2).

M—OH+M′-Cl→M—O—M′+HCl (2)

Further, in the case of using organosilane compound or titanium compound M″-Cl (M″ denotes a structure other than the OC₂H₅ terminal portion) with an OC₂H₅ terminal, the molecular layer 3 is formed by being chemically bonded to the oxide layer 4b, through the chemical reaction expressed by the following formula (3).

M—OH+M″(OC₂H₅)→M—O—M′+C₂H₅OH (3)

By forming the molecular layer 3 through the chemical reactions denoted by the foregoing formulas (1) to (3), a molecular layer 3 is formed on the oxide layer 4b. The molecular layer 3 is self-organized and the molecules thereof are oriented with a predetermined order.

In this way, after forming the molecular layer 3 on the substrate 4, the nanotubes 2 are formed on the molecular layer 3. The method of disposing the nanotubes 2 is not particularly limited. Examples of suitable disposing method include a method of directly depositing the nanotubes on the molecular layer 3 by a CVD (Chemical Vapor Deposition) method, a method of moving each nanotube by a scanning probe microscope, and a method using dielectrophoresis. Alternatively, after the nanotubes 2 are formed on the molecular layer 3 on the substrate 4, an electrode is deposited on each nanotube 2 by lithography.

Among those wiring methods for the nanotubes 2, the method using dielectrophoresis is most preferable, as it can easily and securely dispose the nanotubes 2 onto the molecular layer 3, and also enables mass production. More specifically, in the dielectrophoresis method, a pair of electrodes is formed on the substrate 4 and an alternating electric field is applied between the pair of electrodes (electric field application process). Then, the nanotubes 2 are dispersed to a solvent of methanol or ethanol to prepare a dispersion solution, and the dispersion solution is dropped between the pair of electrodes (dispersion solution dropping process). Note that, the application of alternating electric field between the pair of electrodes should be before evaporation of the solvent, after dropping the dispersion solution.

As a result, the nanotubes 2 are disposed between the pair of electrodes by electrophoresis. Thereafter, the remaining dispersion solution and the nanotubes 2 are collected to complete the molecular device 1 in which the nanotubes 2 are disposed on desired positions. Note that, the provision of nanotubes 2 can be confirmed by monitoring changes in electric resistance between the electrodes. More specifically, a certain electric resistance indicates the provision of the nanotubes 2.

The present invention is not limited to the description of the embodiments above, but may be altered by a skilled person within the scope of the claims. An embodiment based on a proper combination of technical means disclosed in different embodiments is encompassed in the technical scope of the present invention.

In addition to the foregoing arrangement, the molecular device according to the present invention is preferably arranged so that said hydrophobic membrane is formed of an organosilane compound.

With the foregoing arrangement, the hydroxyl group of the surface of the oxide layer formed on the substrate is chemically reacted with the organosilane compound, and the oxide layer and the organosilane compound are chemically bonded, forming a self-organizing monomolecular layer on the oxide layer. In this way, a self-organizing monomolecular layer may be easily formed on an oxide layer.

In addition to the foregoing arrangement, the molecular device according to the present invention is further arranged so that said nano structures are either nanotubes or nanowires.

With the foregoing arrangement, it becomes possible to realize a molecular device in which a micro electronic element, such as a transistor or a capacitor, and/or a wire is made of a nanotube or a nanowire with an easy method. Further, since the provision of hydrophobic membrane reduces interaction between the substrate and the nanotube and/or the nanowire, it becomes possible to realize a highly-reliable molecular device.

In addition to the foregoing arrangement, the method for manufacturing a molecular device according to the present invention is preferably arranged so that said hydrophobic membrane is formed of an organosilane compound, and the step (i) is carried out by chemically reacting a hydroxyl group on the surface of the oxide formed on the substrate with said organosilane compound.

With the foregoing method, the hydroxyl group of the surface of the oxide layer formed on the substrate is chemically reacted with the organosilane compound, and the oxide layer and the organosilane compound are chemically bonded, forming a self-organizing monomolecular layer on the oxide layer. In this way, a self-organizing monomolecular layer may be easily formed on an oxide layer.

In addition to the foregoing arrangement, the manufacturing method for a molecular device according to the present invention may further comprise the step of: (iii) forming a pair of electrodes on the surface of the oxide formed on the substrate, the step (ii) including the sub-steps of: (a) applying an alternating electric field between the pair of electrodes formed in the step (iii); and (b) dropping between the pair of electrodes a dispersion solution in which the nano structures are dispersed.

With the foregoing method, the nano structures may be easily and securely disposed between the electrodes by either dropping, or by dropping the dispersion solution between the electrodes and then applying an alternating electric field between the electrodes. Accordingly, it becomes possible to realize a molecular device in which a micro electronic element, such as a transistor or a capacitor, and/or a wire is made of a nano structure with an easy method. Further, since the nanostructures are formed on a monomolecular layer, interaction between the substrate and the nano structures is reduced. On this account, it becomes possible to realize a highly-reliable molecular device.

As described, the molecular device according to the present invention is arranged so that a substrate includes an oxide layer made of an oxide, the oxide layer including on its surface a hydrophobic membrane which is chemically bonded with the surface, said hydrophobic membrane being a self-organizing monomolecular layer, and the nanostructures being arranged on said hydrophobic membrane.

Further, as described, the manufacturing method for a molecular device according to the present invention comprises the steps of: (i) forming a hydrophobic membrane, which is a self-organizing monomolecular layer, on the oxide on a surface of the oxide layer by chemically bonding the hydrophobic membrane with a surface of the oxide; and (ii) arranging the nano structures on said hydrophobic membrane.

On this account, since the provision of hydrophobic membrane reduces interaction between the substrate and the nano structures, it becomes possible to dispose the nanostructures on desired portions of the substrate via the hydrophobic membrane. In this way, the present invention realizes a highly-reliable molecular device.

### EXAMPLE

The present invention is more specifically explained with reference to a concrete example and a comparative example. The present invention is however not limited to the example below.

### Example 1

At least one pair of Au electrodes 20 nm in film thickness was formed by photolithography on a silicon substrate (substrate) including a Si conductive layer and a SiO2 oxide layer (300 nm in film thickness). The gap between the two electrodes was set to 3 μm. Thereafter, the surface of the silicon substrate was subjected to ozone cleaning, and then the washed silicon substrate and HMDS (hexamethyldisilazane) were supplied to a Teflon® hermetic container. Then, the substrate and the HMDS was placed in an oven together with the hermetic container, and were heated for two hours at 100° C. At this stage, to avoid deterioration of layer by the bad influence of the moisture in the air during formation of monomolecular layer, the internal space of oven was set to nitrogen atmosphere by gas replacement. With this heating process, monomolecular layer was formed on the oxide layer of silicon substrate, excluding the region where the Au electrodes were formed.

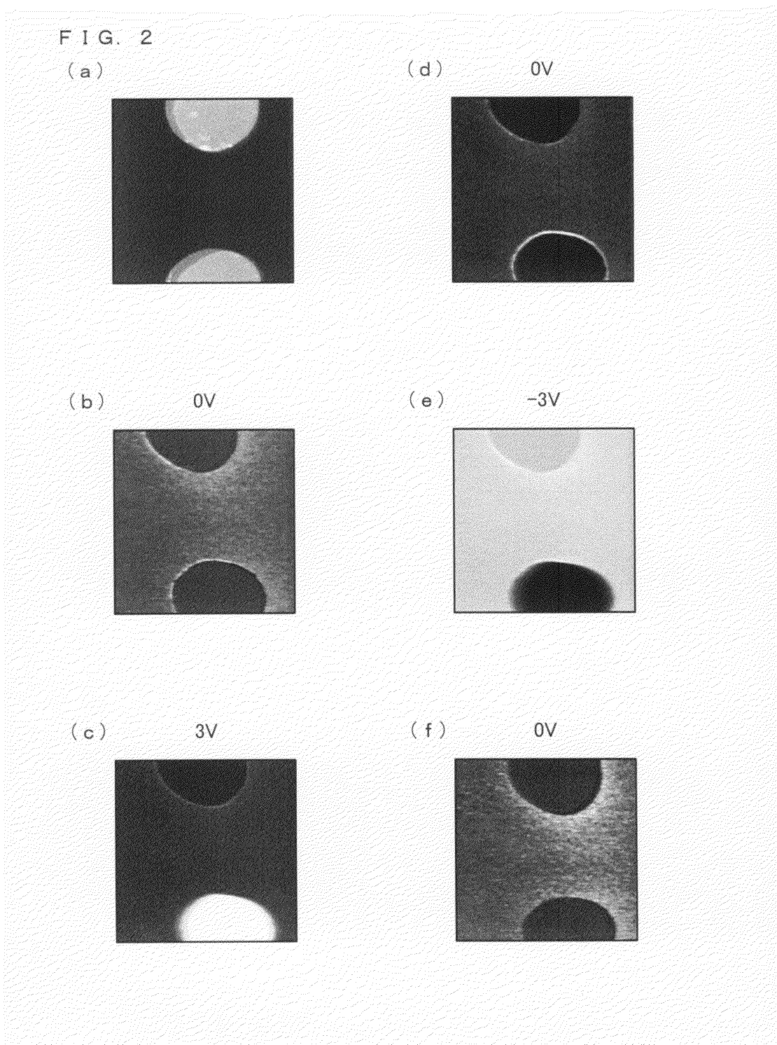

Between the pair of electrodes thus provided on the silicon substrate via the monomolecular layer, voltages of 0V, 3V, 0V, −3V and 0V were sequentially applied. Then a local surface potential on the surface of the monomolecular layer for each voltage was measured by KFM (Kelvin probe Force Microscopy). Note that, the KFM is one of the AFM (Atomic Force Microscopy) technologies, which allows acquirement of potential information on the surface of a sample. FIGS. 2(b) to (f) show the results. For reference, a surface picture of silicon substrate is shown in FIG. 2(a). The picture shows a face where the monomolecular layer is formed.

As shown in FIGS. 2(b) to (f), a hysteresis, that is a phenomenon such that the surface potential becomes substantially the same at 0V even though differing voltages are applied between the Au electrodes, was seen. It indicates that charge was trapped into the substrate around electrodes, and that the formation of monomolecular layer suppressed the amount of charge supply.

Next, an alternating electric field of 2Vp-p, 1 MHz was applied to Au electrodes on a silicon substrate, and a dispersion solution in which carbon nanotubes (nanotube, nano structure) were dispersed in ethanol was dropped. Then carbon nanotubes were crosslinked and disposed between the Au electrodes. Note that, the alternating electric field applied between Au electrodes by dielectrophoresis method is not limited to the example above, as long as it is a relatively high-frequency sine wave of several MHz and amplitude V. The number of the crosslinked CNT increases with an increase of amplitude.

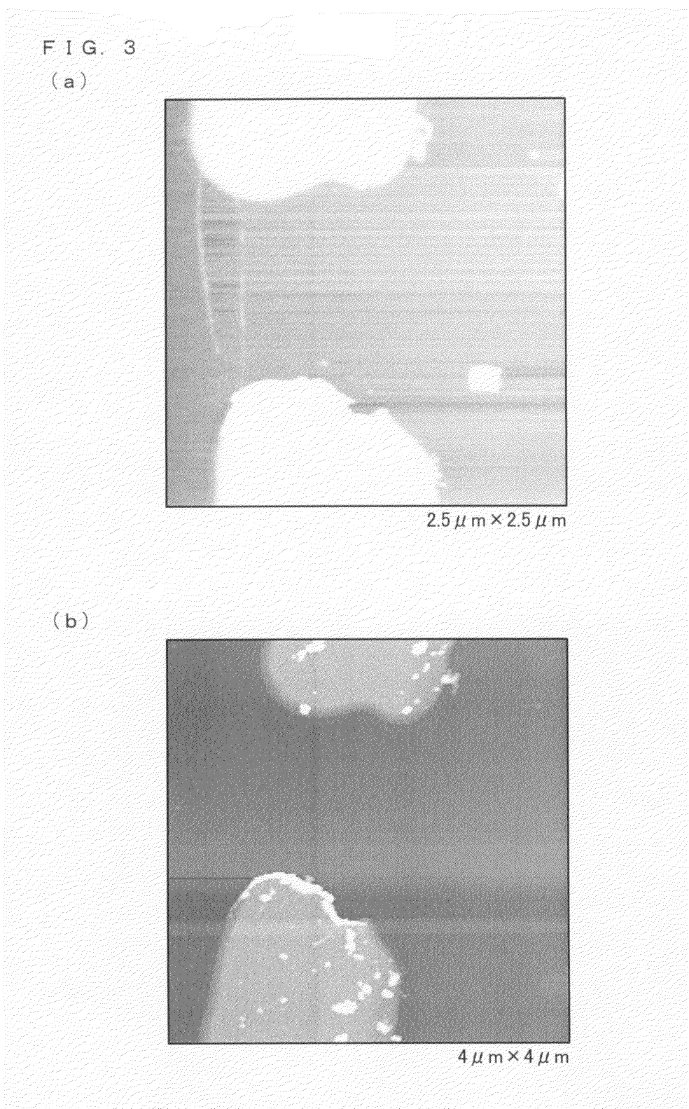

The surface of monomolecular layer of silicon substrate with the nanotubes thus arranged was observed with an AFM (Atomic Force Microscopy). Further, the silicon substrate was soaked into acetone and washed by an ultrasonic cleaner for 15 minutes, and the surface of the monomolecular layer was observed again by the AFM. FIGS. 3(a) and 3(b) show the results. In the figure, the white shadows appearing on an upper and a lower portions are Au electrodes. As shown in FIG. 3(a), the carbon nanotubes were seen arranged between Au electrodes before the ultrasonic cleaning, but as shown in FIG. 3(b), the carbon nanotubes were not seen after the ultrasonic cleaning. The experiment with ultrasonic cleaning was carried out plural times with the same results, which shows that the arranging carbon nanotubes on a silicon substrate via a monomolecular film allows the carbon nanotubes to be easily removed from the silicon substrate.

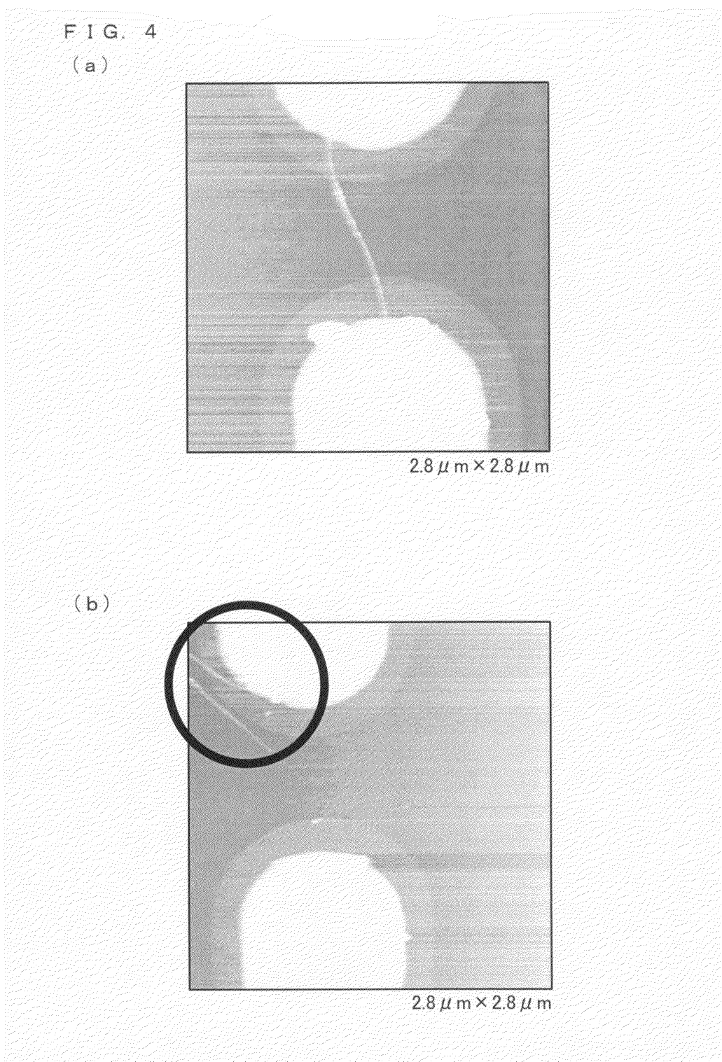

Next, the surface of the silicon substrate on which the crosslinked carbon nanotubes was scanned by a contact-mode AFM in such a manner that the cantilever of AFM passes over the crosslinked carbon nanotubes between the Au electrodes. The load in scanning was increased by 10 nN for each time. Under this condition, the manipulation of carbon nanotube was carried out. FIGS. 4(a) and 4(b) show the results. As shown in FIG. 4(a), the carbon nanotubes, which had been arranged between the Au electrodes before the scanning by the contact AFM, were greatly moved after the scanning with a 40 nN load, as shown in the circle of FIG. 4(b).

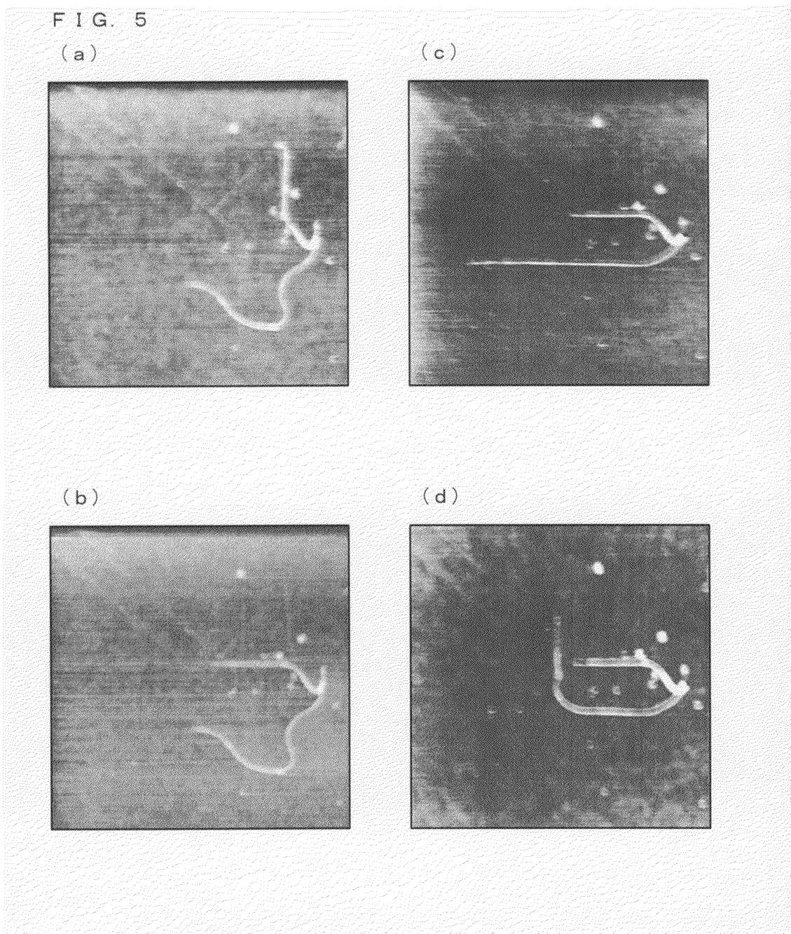

Further, after plural scannings with some loads 100 nN at maximum, as respectively shown in FIGS. 5(a) to (d), it was found that the carbon nanotubes arranged on a silicon substrate via the monomolecular layer were movable (manipulatable). Note that, with a monomolecular layer on a silicon substrate, the manipulation of carbon nanotubes was able to be carried out on condition that the load was 20 nN or greater.

### Comparative Example

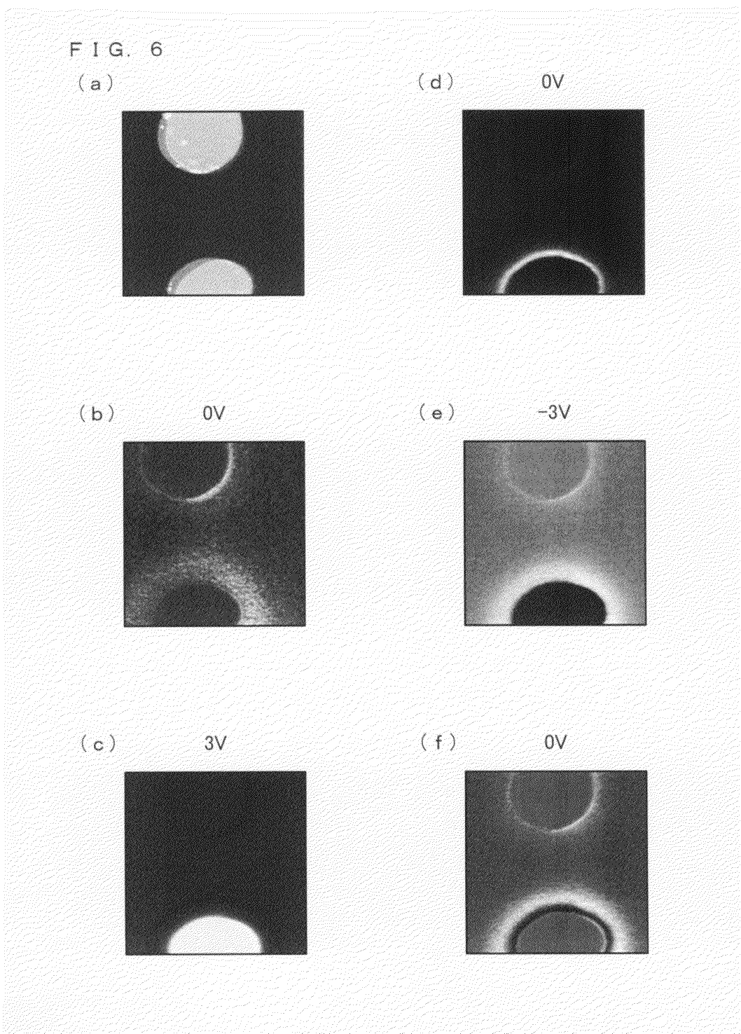

At least a pair of Au electrodes was formed on a silicon substrate in the same manner as that of Example 1. Thereafter, in the same manner as that of Example 1, voltages of 0V, 3V, 0V, −3V and 0V were sequentially applied between the pair of Au electrodes on the surface of the silicon substrate not containing a monomolecular layer. Then a local surface potential on the surface of the monomolecular film for each voltage was measured by KFM (Kelvin probe Force Microscopy). FIGS. 6(b) to (f) show the results. For reference, a surface picture of silicon substrate is shown in FIG. 6(a). The picture shows a face where the Au electrodes are formed.

As can be seen in comparison with FIGS. 2(b) to 2(f) which show the results of Example 1, in the silicon substrate according to the comparative example, the repeated applications of voltages between the Au electrodes made the surface potential on voltage application of 0V in the vicinity of the Au electrode to gradually increase, and finally the hysteresis was hardly seen as shown in FIGS. 6(b), (d) and (f). This shows that the silicon substrate without a monomolecular layer does not have the effect of suppressing the amount of charge supply.

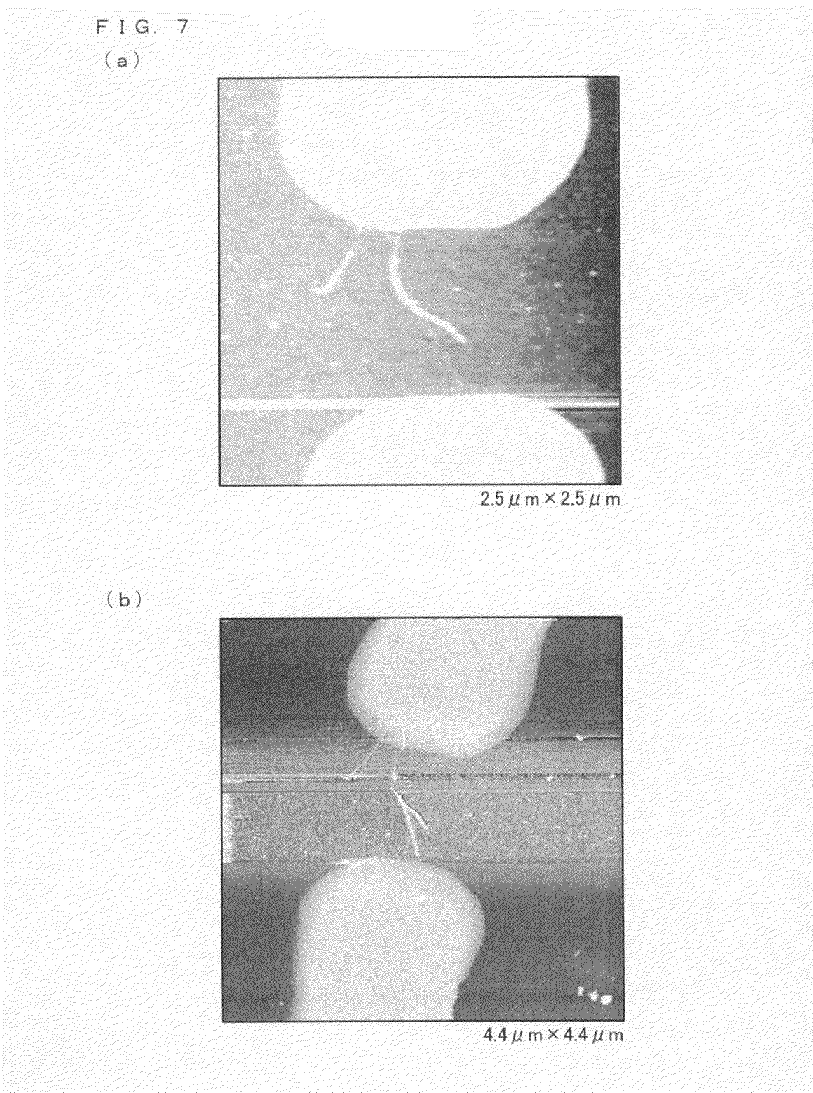

Next, in the same manner as that of Example 1, crosslinked carbon nanostructures were arranged between the Au electrodes on the silicon substrate (not having a monomolecular layer). Then the surface of the silicon substrate was observed by an AFM. Further, the silicon substrate was soaked in acetone and washed by an ultrasonic cleaner for 60 minutes, and the surface of the resulting silicon substrate was observed by the AFM. FIGS. 7(a) and 7(b) show the results. As shown in FIGS. 7(a) and 7(b), the carbon nanotubes arranged between the electrodes were observed both before and after the ultrasonic cleaning.

In comparison with FIGS. 3(a) and 3(b) which show the results of Example 1, it was found that the carbon nanostructures are not easily removed when they are formed on a silicon substrate not having a monomolecular film.

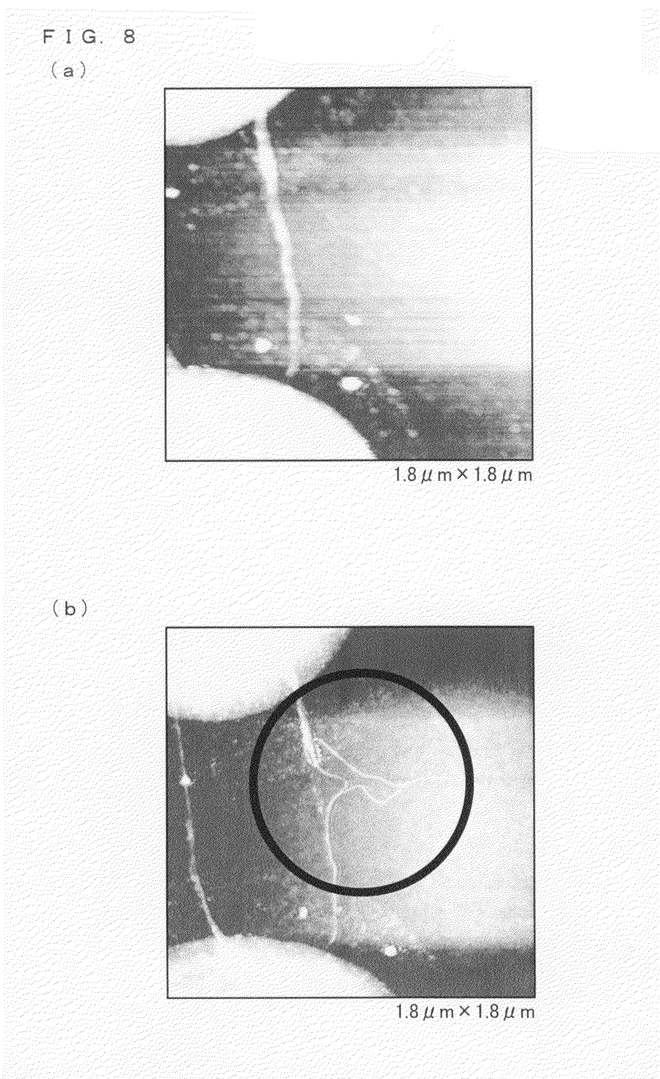

Next, in the same manner as that of Example 1, manipulation of crosslinked carbon nanotubes arranged between the electrodes on the silicon substrate not having a monomolecular layer was evaluated. FIG. 8(a) and 8(b) show the results. As shown in FIG. 8(a), before the scanning by the contact AFM, the carbon nanotubes arranged between the Au electrodes were hardly moved even with an increase in load to 80 nN, and only raveling of the carbon nanotubes was observed, as shown by the circuit in FIG. 8(b).

In comparison with FIGS. 4(a) and 4(b) which show the results of Example 1, it was found that the carbon nanostructures are not easily manipulated when they are formed on a silicon substrate not having a monomolecular film.

### INDUSTRIAL APPLICABILITY

The molecular device of the present invention is useful for next-generation silicon semiconductor element, next generation LSI, next generation optical element or the like, as a replacement of current silicon semiconductor element.

1. A molecular device in which nano structures are arranged on a substrate,
said substrate including an oxide layer made of an oxide,
the oxide layer including on its surface a hydrophobic membrane which is chemically bonded with the surface,
said hydrophobic membrane being a self-organizing monomolecular layer, and the nanostructures being arranged on said hydrophobic membrane.

2. The molecular device as set forth in claim 1 wherein said hydrophobic membrane is formed of an organosilane compound.

3. The molecular device as set forth in claim 1, wherein said nano structures are made of nanotubes and/or nanowires.

4. A manufacturing method of a molecular device in which nano structures are arranged on a substrate including on its surface an oxide layer made of an oxide,
the method comprising the steps of:
(i) forming a hydrophobic membrane, which is a self-organizing monomolecular layer, on the oxide on a surface of the oxide layer by chemically bonding the hydrophobic membrane with a surface of the oxide; and
(ii) arranging the nano structures on said hydrophobic membrane.

5. The method for manufacturing a molecular device as set forth in claim 4, wherein said hydrophobic membrane is formed of an organosilane compound, and the step (i) is carried out by chemically reacting a hydroxyl group on the surface of the oxide formed on the substrate with said organosilane compound.

6. The method for manufacturing a molecular device as set forth in claim 4, further comprising the step of:
(iii) forming a pair of electrodes on the surface of the oxide formed on the substrate, the step (ii) including the sub-steps of:
(a) applying an alternating electric field between the pair of electrodes formed in the step (iii); and
(b) dropping between the pair of electrodes a dispersion solution in which the nano structures are dispersed.

7. The molecular device as set forth in claim 2, wherein said nano structures are made of nanotubes and/or nanowires.

8. The method for manufacturing a molecular device as set forth in claim 5, further comprising the step of:
(iii) forming a pair of electrodes on the surface of the oxide formed on the substrate, the step (ii) including the sub-steps of:
(a) applying an alternating electric field between the pair of electrodes formed in the step (iii); and
(b) dropping between the pair of electrodes a dispersion solution in which the nano structures are dispersed.
